(19) United States
(12) Patent Application Publication
(10) Pub. No.: US 2016/0217997 A1
(43) Pub. Date: Jul. 28, 2016

(54) SUBSTRATE PROCESSING DEVICE, RECORDNG MEDIUM, AND CONTROL METHOD

(71) Applicant: Kabushiki Kaisha Toshiba, Minato-ku (JP)

(72) Inventor: Tomoyuki TAKEISHI, Yokkaichi (JP)

(73) Assignee: Kabushiki Kaisha Toshiba, Minato-ku (JP)

(21) Appl. No.: 14/715,803

(22) Filed: May 19, 2015

(30) Foreign Application Priority Data
Jan. 23, 2015 (JP) 2015-011156

(51) Int. Cl. H01L 21/02; B05C 13/00; G05B 19/418; B05C 11/10

(52) U.S. Cl. CPC H01L 21/02; B05C 11/10; B05C 13/00; G05B 19/418; G05B 2219/45031

(57) ABSTRACT

According to one embodiment, a substrate processing device includes a nozzle that discharges chemical to a circumferential edge portion of a substrate; and a rotation processing unit that rotates the substrate. The substrate processing device also includes a determination unit and a rotation number control unit. The determination unit determines whether or not a discharging position of the chemical by the nozzle arrived at an outer circumferential portion of the substrate from a position on an outer side of the substrate. The rotation number control unit controls a rotation number of the substrate based on a determination result by the determination unit.

### CROSS-REFERENCE TO RELATED APPLICATIONS

This application is based upon and claims the benefit of priority from Japanese Patent Application No. 2015-011156, filed on Jan. 23, 2015; the entire contents of which are incorporated herein by reference.

### FIELD

An embodiment described herein relate generally to a substrate processing device, a recording medium, and a control method.

### BACKGROUND

In a process for manufacturing a semiconductor device, an applying process of a resist, an exposure process, a developing process, an etching process, and the like are carried out after forming various films on a substrate. As etching is carried out over plural times on a circumferential edge portion of such substrate, the etching advances excessively at the circumferential edge portion compared to the center portion of the substrate. Thus, pin-like protrusions sometimes form at the circumferential edge portion of the substrate. Such protrusion is microscopic compared to a trench pattern, and the like, and thus is peeled from the substrate when washing the substrate, and the like. Such peeled protrusion may reattach to the substrate and become a dust.

Thus, a process of forming a protective film on the circumferential edge portion so that the pin-like protrusions do not form at the circumferential edge portion of the substrate has been proposed. However, it is difficult to homogeneously form the protective film of a desired film thickness.

### BRIEF DESCRIPTION OF THE DRAWINGS

FIG. 1 is a view illustrating a configuration of a substrate processing device according to an embodiment;

FIG. 2 is a view illustrating a configuration of a control device according to the embodiment;

FIGS. 3A and 3B are views for describing a relationship of a chemical discharging position and a rotation number according to the embodiment;

FIG. 4 is a view for describing a position relationship of a nozzle and a camera in the substrate processing device according to the embodiment;

FIG. 5 is a flowchart illustrating an application process procedure of the substrate processing device according to the embodiment;

FIG. 6 is a view illustrating a different configuration example of a discharging unit according to the embodiment;

FIGS. 7A and 7B are views illustrating a first arrangement example of the camera according to the embodiment when the discharging unit and the camera have different configurations;

FIGS. 8A and 8B are views illustrating a second arrangement example of the camera according to the embodiment when the discharging unit and the camera have different configurations; and

FIG. 9 is a view illustrating a hardware configuration of a control device.

### DETAILED DESCRIPTION

According to the embodiment, the substrate processing device is provided. The substrate processing device includes a nozzle that discharges chemical to a circumferential edge portion of a substrate, and a rotation processing unit that rotates the substrate. The substrate processing device also includes a determination unit and a rotation number control unit. The determination unit determines whether or not a discharging position of the chemical by the nozzle arrived at an outer circumferential portion of the substrate from a position on an outer side of the substrate. The rotation number control unit controls a rotation number of the substrate based on the determination result of the determination unit.

An exemplary embodiment of a substrate processing device, a recording medium, and a control method will be explained below in detail with reference to the accompanying drawings. The present invention is not limited to the following embodiment.

### Embodiment

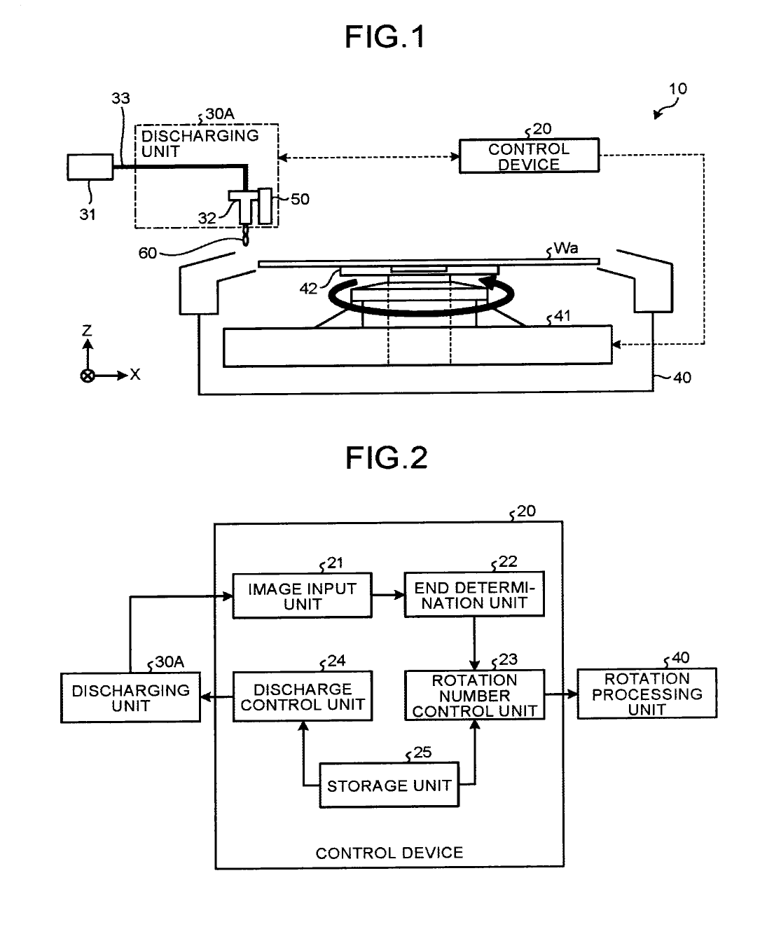

FIG. 1 is a view illustrating a configuration of a substrate processing device according to an embodiment. In FIG. 1, a cross-sectional configuration example of a substrate processing device 10 is illustrated. The substrate processing device 10 is a device that discharges a chemical 60 to a circumferential edge portion of a wafer Wa while rotating a processing substrate (wafer Wa) at a predetermined rotation number. A film (hereinafter described as protective film 61) applied with the chemical 60 thereby forms on the circumferential edge portion of the wafer Wa.

The substrate processing device 10 of the present embodiment starts the discharging of the chemical 60 from a nozzle 32, and then approaches the nozzle 32 to above the wafer Wa while rotating the wafer Wa at a first rotation number lower than a predetermined value. When the discharging position of the chemical 60 by the nozzle 32 (hereinafter referred to as chemical discharging position) arrives at an outermost circumferential portion of the wafer Wa, the nozzle 32 is moved by a predetermined distance, and the substrate processing device 10 changes the rotation number of the wafer Wa to a second rotation number higher than the first rotation number.

The substrate processing device 10 thus drops the chemical 60 onto the wafer Wa while rotating the wafer Wa at the second rotation number. Thus, when the chemical discharging position arrives at the outermost circumferential portion of the wafer Wa, the substrate processing device 10 changes the rotation number of the wafer Wa from a low rotation number to a high rotation number. In other words, the substrate processing device 10 starts the discharging of the chemical 60 to the wafer Wa at the first rotation number, and thereafter, carries out the discharging of the chemical 60 to the wafer Wa at the second rotation number. The protective film 61 having the desired film thickness thereby homogeneously forms on the circumferential edge portion (substrate circumferential edge portion) on the wafer Wa according to the control of changing the rotation number.

Hereinafter, a configuration and an operation of the substrate processing device 10 will be described with a plane parallel to the upper surface of the wafer Wa as an XY plane and a direction perpendicular to the upper surface of the wafer Wa as a Z direction.

The substrate processing device 10 is a substrate circumferential edge processing device for selectively supplying the chemical 60 from the nozzle 32 to only the circumferential edge portion of the wafer Wa and forming the protective film 61 on the wafer Wa. The substrate processing device 10 controls the rotation number of the wafer Wa to arbitrarily control the film thickness of the protective film 61.

The substrate processing device 10 includes a control device 20, a discharging unit 30A, and a rotation processing unit 40. The discharging unit 30A includes the nozzle 32, and a camera 50 serving as an example of a discharging position detection unit for detecting the chemical discharging position. The nozzle 32 discharges the chemical 60.

The substrate processing device 10 includes a chemical supply source 31 and a piping 33. The chemical supply source 31 includes a tank, and the like for storing the chemical 60 to be dropped onto the wafer Wa. The piping 33 is connected to the chemical supply source 31 and the nozzle 32. The chemical (processing solution) 60 fed from the chemical supply source 31 is fed to the nozzle 32 through the piping 33, and discharged from a tip of the nozzle 32.

The discharging unit 30A is configured so as to be movable within a plane parallel to the surface of the wafer Wa. When the nozzle 32 discharges the chemical 60 to the wafer Wa, the discharging unit 30A moves to an outer circumferential portion region of the wafer Wa. When the discharging of the chemical 60 to the wafer Wa by the nozzle 32 is completed, the discharging unit 30A moves to the outer side of the wafer Wa.

When the wafer Wa is seen from the upper surface side, the discharging unit 30A carries out a first movement from outside the wafer Wa (outer side of the wafer Wa) to above the wafer Wa, and a second movement from above the wafer Wa to outside the wafer Wa. The discharging unit 30A carries out the first movement and the second movement for every wafer Wa when discharging the chemical 60. The discharging unit 30A carries out the first movement when discharging the chemical 60, and carries out the second movement after the discharging of the chemical 60 is completed.

The camera (imaging unit) 50 is arranged in the vicinity of the nozzle 32. The camera 50 is arranged on the upper surface side of the wafer Wa. When the discharging unit 30A is moved from the outside of the wafer Wa to above the wafer Wa, the camera 50 moves from the outside of the wafer Wa to above the wafer Wa with the nozzle 32. The camera 50 moves from the outside of the wafer Wa to above the wafer Wa while imaging the lower side in the vertical direction.

The camera 50 images portions other than the wafer Wa while moving at the outer side of the wafer Wa. When arriving at the outermost circumferential portion (outer edge portion) of the wafer Wa from outside the wafer Wa, the camera 50 images the outer circumferential portion of the wafer Wa from the upper surface side of the wafer Wa. The camera 50 transmits the imaged image to the control device 20.

The control device 20 is connected to the discharging unit 30A and the rotation processing unit 40. The control device 20 controls the discharging unit 30A and the rotation processing unit 40. The control device 20 of the present embodiment controls the rotation processing unit 40 based on an image (position of the outer circumferential portion of the wafer Wa in the image) transmitted from the camera 50. Specifically, when receiving the image indicating that the chemical discharging position arrived at the outermost circumferential portion of the wafer Wa (image in which the outermost circumferential portion of the wafer Wa is imaged in a predetermined region of the image), the control device 20 transmits an instruction to change the rotation number of the wafer Wa from the low rotation number to the high rotation number to the rotation processing unit 40.

The rotation processing unit 40 supports the wafer Wa so that the upper surface of the wafer Wa becomes parallel to the XY plane. The rotation processing unit 40 rotates the wafer Wa with the center of the wafer Wa as a rotation axis. The rotation processing unit 40 rotates the wafer Wa within a plane parallel to the upper surface of the wafer Wa.

The rotation processing unit 40 includes a rotation mechanism 41 and a supporting mechanism 42. The supporting mechanism 42 supports the wafer Wa from a bottom surface side. The wafer Wa is a substrate such as a semiconductor substrate, for example, and has a circular plate shape. In the wafer Wa, the upper surface is the surface on which the chemical 60 is discharged, and the bottom surface is the surface supported by the supporting mechanism 42.

The rotation mechanism 41 rotates the supporting mechanism 42. The rotation mechanism 41 rotates the supporting mechanism 42 supporting the wafer Wa with the center of the wafer Wa as a rotation axis. The rotation mechanism 41 changes the rotation number of the wafer Wa in accordance with the instruction from the control device 20.

Next, a configuration example of the control device 20 will be described. FIG. 2 is a view illustrating a configuration of the control device according to the embodiment. The control device 20 includes an image input unit 21, an end determination unit (edge detecting unit) 22, a rotation number control unit 23, a discharge control unit 24, and a storage unit 25.

The image input unit 21 receives the image provided from the camera 50 of the discharging unit 30A. The image input unit 21 transmits the received image to the end determination unit 22. The end determination unit 22 detects the chemical discharging position based on the image transmitted from the image input unit 21. For example, the end determination unit 22 detects a coordinate from the outermost circumferential portion of the wafer Wa as the chemical discharging position.

The end determination unit 22 determines whether or not the chemical discharging position arrived at the outermost circumferential portion of the wafer Wa (wafer edge). The end determination unit 22 determines whether or not the chemical discharging position arrived at the outermost circumferential portion of the wafer Wa based on a position relationship of the outermost circumferential portion of the wafer Wa included in the image and the nozzle 32. The end determination unit 22 may determine that the chemical discharging position arrived at the outermost circumferential portion of the wafer Wa if the image of the outermost circumferential portion of the wafer Wa is included in the predetermined region of the received image.

A predetermined distance (arrangement interval) is provided between the position of the camera 50 and the position of the nozzle 32. The end determination unit 22 may correct the detected chemical discharging position using the arrangement interval and a movement speed of the nozzle 32. In this case, the end determination unit 22 determines whether or not the chemical discharging position arrived at the outermost circumferential portion of the wafer Wa based on the chemical discharging position after the correction. When determining that the chemical discharging position arrived at the outermost circumferential portion of the wafer Wa, the end determination unit 22 provides information (hereinafter referred to as arrival notification) indicating that the chemical discharging position arrived at the outermost circumferential portion to the rotation number control unit 23.

The rotation number control unit 23 controls the rotation processing unit 40. The rotation number control unit 23 provides the information instructing the rotation number of the wafer Wa to the rotation processing unit 40. The rotation number control unit 23 controls the rotation processing unit 40 based on the rotation number information (number information specifying the rotation number) stored in the storage unit 25. A rotation number (first rotation number) before the chemical discharging position arrives at the outermost circumferential portion of the wafer Wa, and a rotation number (second rotation number) after the chemical discharging position arrives at the outermost circumferential portion of the wafer Wa are defined in the rotation number information. The second rotation number is a rotation number greater than the first rotation number.

The rotation number control unit 23 transmits an instruction specifying the first rotation number to the rotation processing unit 40 until receiving the arrival notification from the end determination unit 22. The rotation processing unit 40 rotates the wafer Wa at the first rotation number until the chemical discharging position arrives at the outermost circumferential portion of the wafer Wa.

When receiving the arrival notification from the end determination unit 22, the rotation number control unit 23 transmits an instruction specifying the second rotation number to the rotation processing unit 40. The rotation processing unit 40 then rotates the wafer Wa at the second rotation number when the chemical discharging position arrives at the outermost circumferential portion of the wafer Wa.

The discharge control unit 24 controls the discharging unit 30A based on a discharging recipe stored in the storage unit 25. The discharging recipe stores a discharge start timing and a discharge end timing of the chemical 60 by the nozzle 32, an imaging start timing and an imaging end timing of the image by the camera 50, and the like.

The discharging recipe also stores a discharging amount per unit time of the chemical 60, the movement path of the nozzle 32, and the like. In the movement path of the nozzle 32, for example, information (distance from the outermost circumferential portion of the wafer Wa) indicating to which position on the wafer Wa to move the nozzle 32, and the like are defined. The storage unit 25 stores the discharging recipe and the rotation number information.

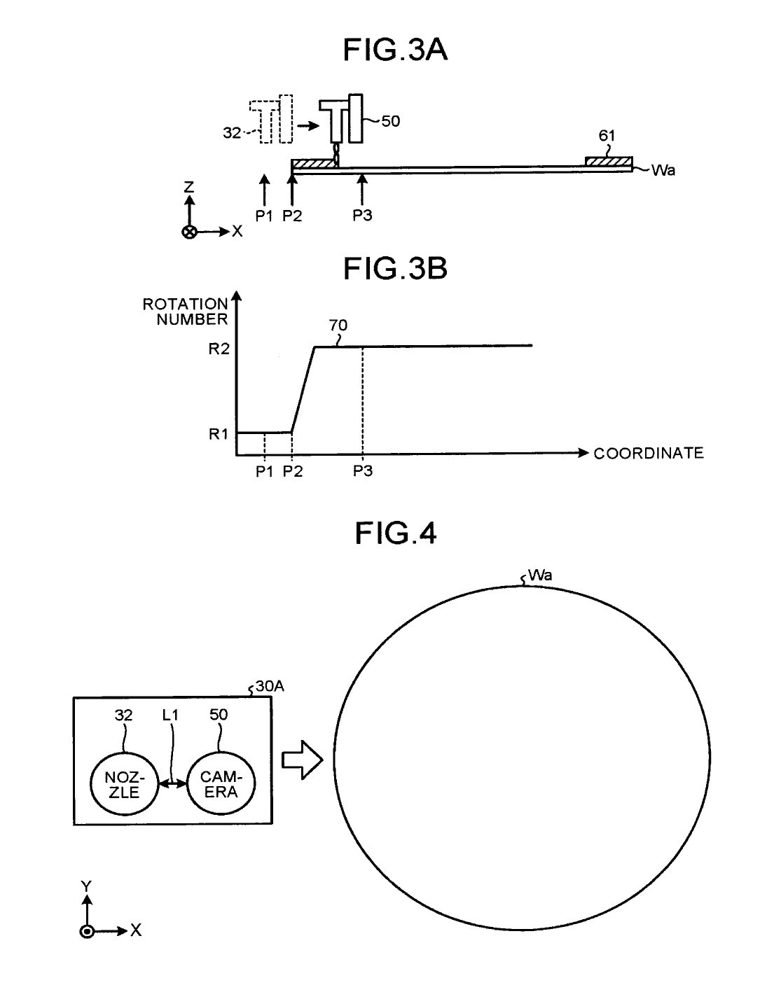

FIGS. 3A and 3B are views for describing a relationship of the chemical discharging position and the rotation number according to the embodiment. FIG. 3A illustrates a cross-sectional view of the wafer Wa, the nozzle 32, the camera 50, and the like. FIG. 3B illustrates a relationship (property 70) of the coordinate of the chemical discharging position and the rotation number of the wafer Wa.

The rotation number control unit 23 controls the rotation processing unit 40 so as to realize the rotation number indicated with the property 70. Specifically, the rotation number control unit 23 controls the rotation processing unit 40 so as to realize the first rotation number R1 while the nozzle 32 (camera 50) is moving at a position P1 on the outer side of the wafer Wa. When the nozzle 32 (camera 50) arrives at a position P2, which is the outermost circumferential portion of the wafer Wa, the rotation number control unit 23 controls the rotation processing unit 40 so as to increase the rotation number of the wafer Wa. When the rotation number of the wafer Wa arrives at the second rotation number R2, which is a target rotation number, the rotation number control unit 23 maintains the second rotation number R2. When the nozzle 32 (camera 50) arrives at a position P3, which is a target applying position of the wafer Wa, thereafter, the nozzle 32 stops the discharging of the chemical 60.

The substrate processing device 10 thus rotates the wafer Wa at the rotation number R1 while the chemical discharging position is between the position P1 and the position P2. After the chemical discharging position arrives at the position P2, the substrate processing device 10 increases the rotation number from the rotation number R1 and rotates the wafer Wa at the rotation number R2.

The protective film (processing film) 61 formed with the chemical 60 is thereby arranged in the outer circumferential region of the wafer Wa. The protective film 61 has a circular ring shape when seen from the upper surface.

FIG. 4 is a view for describing a position relationship of the nozzle and the camera in the substrate processing device according to the embodiment. In FIG. 4, the position relationship of the nozzle 32 and the camera 50 of when the wafer Wa is seen from the upper surface side is illustrated. The nozzle 32 and the camera 50 are arranged in the discharging unit 30A. The nozzle 32 and the camera 50 are arranged at positions spaced apart by a predetermined distance (arrangement spacing) L1. In this case, the end determination unit 22 corrects the detected chemical discharging position using the distance L1 and the movement speed of the nozzle 32. The end determination unit 22 may set the distance to L1=0 and correct the detected chemical discharging position. In this case, the end determination unit 22 corrects the detected chemical discharging position using the movement speed of the nozzle 32.

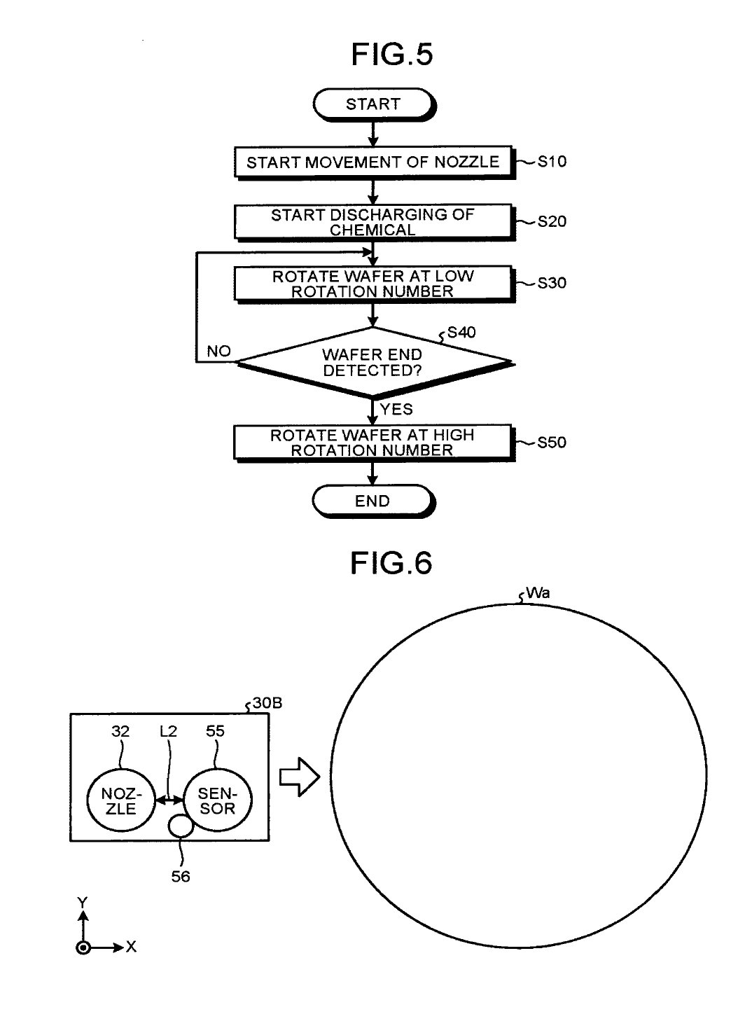

An application process procedure of the chemical 60 by the substrate processing device 10 will now be described. FIG. 5 is a flowchart illustrating the application process procedure of the substrate processing device according to the embodiment. In the substrate processing device 10, the discharge control unit 24 causes the nozzle 32 to start moving (step S10). The discharge control unit 24 moves the nozzle 32 from the position on the outer side of the wafer Wa toward the direction of the center position of the wafer Wa.

The discharge control unit 24 causes the nozzle 32 to start the discharging of the chemical 60 (step S20). The rotation number control unit 23 rotates the wafer Wa at a low rotation number lower than the predetermined value (step S30). The discharge control unit 24 also causes the camera 50 to start the imaging process of the image.

The processes of steps S10 to S30 and the imaging process of the image may be started in any order. The discharge control unit 24 approaches the discharging unit. 30A to the wafer Wa with the wafer Wa rotating at the low rotation number (first rotation number) lower than the predetermined value. The first rotation number is the rotation number that can prevent scattering of the chemicals 60 (generation of mist).

The discharging unit 30A approaches the wafer Wa while the chemical 60 is being discharged from the nozzle 32 and the camera 50 is imaging the image. The camera 50 transmits the imaged image to the image input unit 21. The image input unit 21 transmits the received image to the end determination unit 22. The end determination unit 22 detects the chemical discharging position based on the image transmitted from the image input unit 21. The end determination unit 22 determines whether or not the chemical discharging position arrived at the outermost circumferential portion of the wafer Wa based on the chemical discharging position. In other words, the end determination unit 22 determines whether or not the wafer end is detected as the chemical discharging position (step S40).

If the wafer end is not detected (step S40, No), the end determination unit 22 does not send the arrival notification to the rotation number control unit 23. The rotation number control unit 23 then continues the process of rotating the wafer Wa at the low rotation number lower than the predetermined value (step S30). The end determination unit 22 then determines whether or not the wafer end is detected (step S40).

If the wafer end is detected (step S40, Yes), the end determination unit 22 sends the arrival notification indicating that the chemical discharging position arrived at the outermost circumferential portion of the wafer Wa to the rotation number control unit 23. In other words, the end determination unit 22 sends the arrival notification to the rotation number control unit 23 when detecting that the chemical discharging position crossed the wafer end.

The rotation number control unit 23 increases the rotation number of the wafer Wa when receiving the arrival notification from the end determination unit 22. The rotation number control unit 23 thereby rotates the wafer Wa at a high rotation number (second rotation number) higher than the predetermined value (step S50). The second rotation number is the rotation number that determines the film thickness of the protective film 61. Therefore, the rotation number control unit 23 rotates the wafer Wa at the second rotation number that can form the desired film thickness.

Thus, the rotation number control unit 23 rotates the wafer Wa at the first rotation number for a predetermined time after the chemical discharging position arrives at the outer circumferential portion of the wafer Wa, and rotates the wafer Wa at the second rotation number greater than the first rotation number after the predetermined time has elapsed.

In the substrate processing device 10, the processes of steps S40, S50 described above are executed with the discharging process of the chemical 60 by the nozzle 32 and the process of moving the nozzle 32 in the center direction of the wafer Wa continued.

At the time point the nozzle 32 moved to the predetermined position above the wafer Wa, the nozzle 32 stops the discharging of the chemical 60. The chemical 60 is thus applied only to the outer circumferential region of the wafer Wa. After the application of the chemical 60 to the wafer Wa is completed, the nozzle 32 is returned to the initial position, and the rotation of the wafer Wa is stopped. In the rotation processing unit 40, the wafer Wa completed with application is discharged and a new wafer Wa is conveyed therein. The substrate processing device 10 executes the processes of steps S10 to S50 described above with respect to the new wafer Wa.

In the present embodiment, a case of detecting the wafer end using the camera 50 has been described, but the substrate processing device 10 may detect the wafer end using a sensor (light quantity detection unit). FIG. 6 is a view illustrating another configuration example of the discharging unit according to the embodiment. In FIG. 6, a configuration of a discharging unit 308 when the wafer Wa is seen from the upper surface side is illustrated.

The discharging unit 308 includes a sensor 55 and a light source 56 in place of the camera 50. The sensor 55 serves as an example of a discharging position detection unit, and is, for example, a CCD (Charge Coupled Device) sensor. The light source (irradiation unit) 56 is, for example, a laser light source. The light source 56 is arranged in the vicinity of the sensor 55.

The light source 56, for example, exits light such as a laser light, and the sensor 55 detects the reflected light quantity thereof. The sensor 55 provides the detected reflected light quantity to the control device 20. Thus, the end determination unit 22 detects the wafer end based on the reflected light quantity.

The nozzle 32 and the sensor 55 are arranged at positions spaced apart by a predetermined distance (arrangement spacing) L2. In this case, the end determination unit 22 corrects the detected chemical discharging position using the distance L2 and the movement speed of the nozzle 32. The end determination unit 22 may set the distance to L2=0, and correct the detected chemical discharging position. In this case, the end determination unit 22 corrects the detected chemical discharging position using the movement speed of the nozzle 32.

The discharge control unit 24 moves the discharging unit 308 from the outer side of the wafer Wa toward the center portion side of the wafer Wa while the light source 56 is exiting the laser light. The sensor 55 detects the reflected light quantity lower than a predetermined value while the sensor 55 is moving at the position on the outer side of the wafer Wa. When the sensor 55 moves to the wafer end, the sensor 55 detects the reflected light quantity higher than the predetermined value.

The end determination unit 22 determines that the chemical discharging position is on the outer side of the wafer Wa when the reflected light quantity is lower than the predetermined value. The end determination unit 22 determines that the chemical discharging position arrived at the wafer end when the reflected light quantity is higher than the predetermined value.

In the present embodiment, a case in which the discharging unit 30A includes the camera 50 has been described, but the discharging unit 30A and the camera (cameras 51, 52 to be described later) may have different configurations. In this case, the cameras 51, 52 image the nozzle 32. The end determination unit 22 determines whether or not the chemical discharging position is at the wafer end based on the position of the nozzle 32.

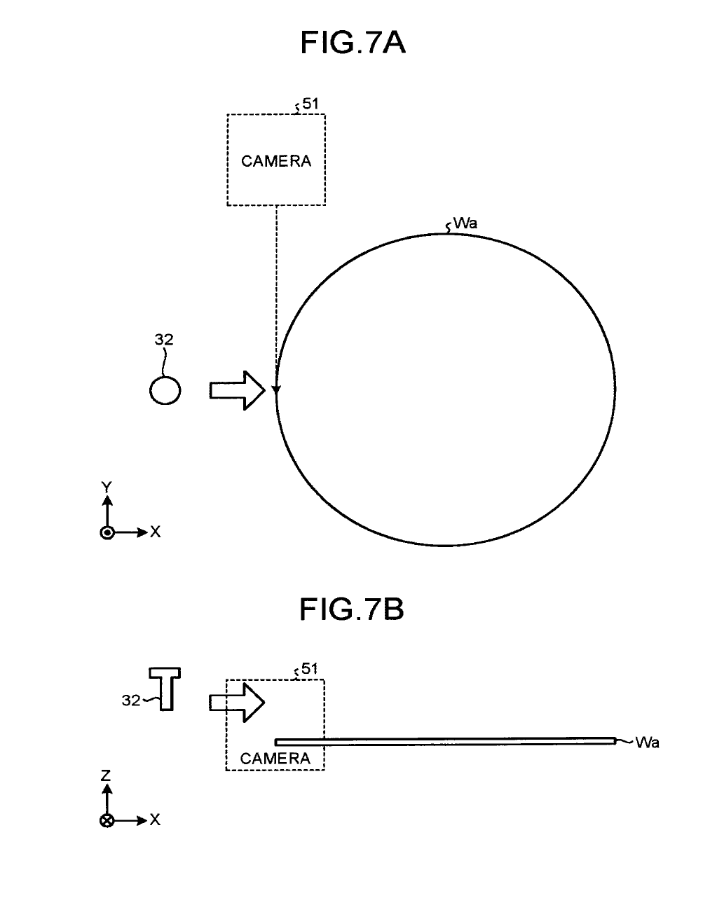

FIGS. 7A and 7B are views illustrating a first arrangement example of the camera according to the embodiment when the discharging unit and the camera have different configurations. FIG. 7A illustrates the arrangement position of the camera 51 when the wafer Wa is seen from the upper surface side, and FIG. 7B illustrates the arrangement position of the camera 51 when the wafer Wa is seen from the side surface side. The camera 51 has a function similar to the camera 50.

If the discharging unit 30A and the camera 51 have different configurations, the camera 51 is fixedly arranged at the position where the wafer end can be imaged. For example, the camera 51 is arranged at the position where the side surface of the wafer end can be imaged. Specifically, the camera 51 is arranged at a position spaced apart from the wafer Wa by a predetermined distance within a plane (same Z coordinate as the wafer Wa) parallel to the upper surface of the wafer Wa. In this case, the camera 51 images the nozzle 32 moving from the outer side of the wafer Wa to the wafer end. When receiving the image in which the position of the nozzle 32 is at the upper part of the wafer end, the end determination unit 22 determines that the chemical discharging position is at the wafer end.

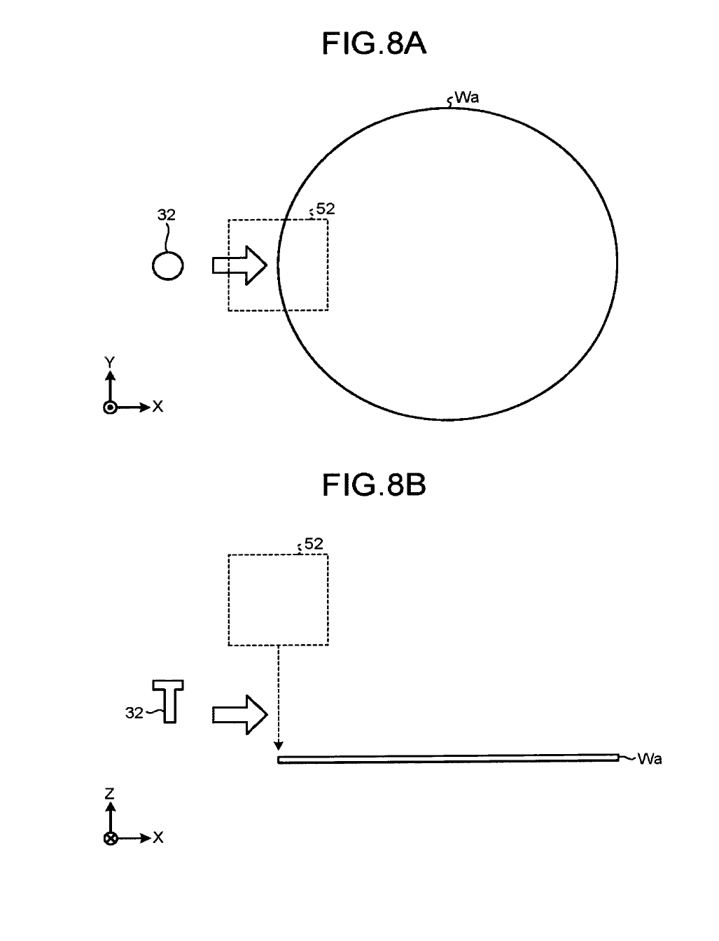

FIGS. 8A and 8B are views illustrating a second arrangement example of the camera according to the embodiment of when the discharging unit and the camera have different configurations. FIG. 8A illustrates the arrangement position of the camera 52 when the wafer Wa is seen from the upper surface side, and FIG. 8B illustrates the arrangement position of the camera 52 when the wafer Wa is seen from the side surface side. The camera 52 has a function similar to the camera 50.

If the discharging unit 30A and the camera 52 have different configurations, the camera 52 is fixedly arranged at the position where the wafer end can be imaged. For example, the camera 52 is arranged at the position where the upper surface of the wafer end can be imaged. Specifically, the camera 52 is arranged at the position spaced apart from the wafer Wa by a predetermined distance at the upper part of the wafer end. In this case, the camera 52 images the nozzle 32 moving to the wafer end. When receiving the image in which the position of the nozzle 32 is the upper part of the wafer end, the end determination unit 22 determines that the chemical discharging position is at the wafer end.

Discharging process of the chemical 60 is executed by the substrate processing device 10 with various wafer processes (e.g., before etching process). When the semiconductor device (semiconductor integrated circuit) is manufactured, the exposure process is executed on the wafer Wa applied with the resist. Thereafter, the wafer Wa is developed and a resist pattern is formed on the wafer Wa. Subsequently, the chemical 60 is applied to the wafer Wa by the substrate processing device 10, as necessary. The lower layer side of the resist pattern is etched with the resist pattern and the protective film 61 as a mask. Thus, an actual pattern corresponding to the resist pattern is formed on the wafer Wa. When manufacturing the semiconductor device, the exposure process, the developing process, the application process of the chemical 60, the etching process, and the like described above are repeated for every layer. When manufacturing the semiconductor device, an imprint process, and the like may be used in place of the exposure process and the developing process.

In the manufacturing process of the semiconductor device, a silicon nitride film and a silicon oxide film are formed on the wafer Wa, which is a silicon substrate, with a CVD (Chemical Vapor Deposition) device, and the like. Thereafter, the application of the resist, the exposure, the development, and the like are carried out. The resist pattern is thereby formed on the wafer Wa. Next, the etching is carried out with the formed resist pattern as a mask, whereby a trench and a contact via to become a capacitor are formed.

Since the outer circumferential region of the wafer Wa is etched over a plurality of times, the etching advances excessively thereat compared to the center portion of the wafer Wa unless the protective film 61 is arranged. As a result, the pin-like protrusions form in the outer circumferential region of the wafer Wa unless the protective film 61 is arranged.

Thus, in the present embodiment, the protective film 61 is formed in the outer circumferential portion region of the wafer Wa so that the pin-like protrusions are not formed. In the present embodiment, the chemical 60 is dropped onto the wafer Wa while rotating the wafer Wa at the low rotation number until the chemical discharging position arrives at the wafer end. The chemical 60 is thus dropped onto the wafer end while rotating the wafer Wa at the low rotation number. After the chemical discharging position arrives at the wafer end, the chemical 60 is dropped on the wafer Wa while rotating the wafer Wa at the high rotation number.

Thus, the substrate processing device 10 can prevent scattering of the chemical 60 onto the wafer Wa since the chemical 60 is dropped on the wafer end while rotating the wafer Wa at the low rotation number. Furthermore, the substrate processing device 10 drops the chemical 60 on the wafer end while rotating the wafer Wa at the high rotation number after the chemical discharging position arrives at the wafer end, and thus the protective film 61 having the desired thickness can be formed on the wafer Wa.

Therefore, the substrate processing device 10 can homogeneously form the protective film 61 having the desired film thickness in the outer circumferential portion region on the wafer Wa. The homogeneous protective film 61 can be formed in the outer circumferential portion region without depending on the diameter of the wafer Wa. The process margin of the film thickness, and the like can be enhanced even with respect to the wafer Wa having a large warp amount.

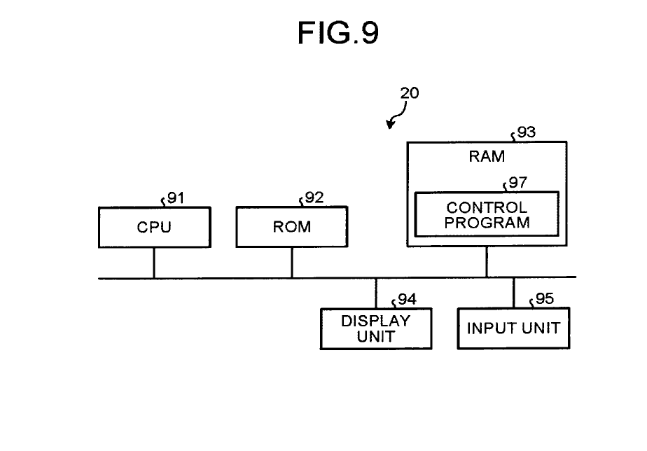

Next, a hardware configuration of the control device 20 will be described. FIG. 9 is a view illustrating a hardware configuration of the control device. The control device 20 includes a CPU (Central Processing Unit) 91, a ROM (Read Only Memory) 92, a RAM (Random Access Memory) 93, a display unit 94, and an input unit 95. In the control device 20, the CPU 91, the ROM 92, the RAM 93, the display unit 94, and the input unit 95 are connected by way of a bus line.

The CPU 91 controls the rotation number of the wafer Wa using a control program 97, which is a computer program. The control program 97 is a computer program product including a nontransitory computer readable recording medium with a plurality of commands for controlling the rotation number of the wafer Wa executable with a computer. In the control program 97, the plurality of commands causes the computer to execute the control of the rotation number of the wafer Wa.

The display unit 94 is a display device such as a liquid crystal monitor, and the like, and displays the rotation number of the wafer Wa, the chemical discharging position (coordinate from the wafer Wa), the image imaged by the camera 50, and the like on the basis of an instruction from the CPU 91. The input unit 95 is configured to include a mouse and a keyboard, and inputs instruction information (parameter necessary for the rotation number control of the wafer Wa, rotation number information, etc.) externally input from the user. The instruction information input to the input unit 95 is transmitted to the CPU 91.

The control program 97 is stored in the ROM 92, and is loaded to the RAM 93 through the bus line. In FIG. 9, a state in which the control program 97 is loaded to the RAM 93 is illustrated.

The CPU 91 executes the control program 97 loaded in the RAM 93. Specifically, in the control device 20, the CPU 91 reads out the control program 97 from the ROM 92 and develops the control program in a program storage region in the RAM 93 to execute various types of processes according to an instruction input from the input unit 95 by the user. The CPU 91 temporarily stores the various types of data generated in the various types of processing in a data storage region formed in the RAM 93.

The control program 97 executed by the control device 20 has a module configuration including the end determination unit 22 and the rotation number control unit 23, which are loaded on a main storage device and generated on the main storage device.

In FIGS. 4 and 6, a case in which the positions of the camera 50 and the sensor 55 are arranged closer to the wafer Wa than the position of the nozzle 32 has been described, but the position of the nozzle 32 may be arranged closer to the wafer Wa than the positions of the camera 50 and the sensor 55. Furthermore, the nozzle 32 and the camera 50 may be arranged such that the position of the nozzle 32 from the wafer Wa and the position of the camera 50 from the wafer Wa are the same. The sensor 55 and the nozzle 32 may be arranged such that the position of the nozzle 32 from the wafer Wa and the position of the sensor 55 from the wafer Wa are the same.

Thus, in the embodiment, the rotation number of the wafer Wa is controlled based on the determination result on whether or not the chemical discharging position arrived at the outer circumferential portion of the wafer Wa from the outer side of the wafer Wa. The scattering of the chemical 60 on the wafer Wa thus can be prevented. Furthermore, the protective film 61 can be formed to the desired film thickness. Therefore, the protective film 61 having the desired film thickness can be homogeneously formed on the wafer Wa.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate processing device comprising:
a nozzle configured to discharge chemical to a circumferential edge portion of a substrate;
a rotation processing unit configured to rotate the substrate;
a determination unit configured to determine whether or not a discharging position of the chemical by the nozzle arrived at an outer circumferential portion of the substrate from a position on an outer side of the substrate; and
a rotation number control unit configured to control a rotation number of the substrate based on a determination result by the determination unit.

2. The substrate processing device according to claim 1, wherein the rotation number control unit rotates the substrate at a first rotation number for a predetermined time from when the discharging position arrives at the outer circumferential portion of the substrate, and rotates the substrate at a second rotation number greater than the first rotation number after the predetermined time has elapsed.

3. The substrate processing device according to claim 1, further comprising a discharging position detection unit configured to detect the discharging position and transmit the discharging position to the determination unit.

4. The substrate processing device according to claim 3, wherein
the discharging position detection unit includes an imaging unit configured to image the outer circumferential portion of the substrate and transmit an imaged image to the determination unit; and
the determination unit determines whether or not the discharging position arrived at the outer circumferential portion of the substrate based on a position of the outer circumferential portion in the image.

5. The substrate processing device according to claim 4, wherein the imaging unit moves with the nozzle, and images an upper surface of the substrate when the discharging position arrives at the outer circumferential portion of the substrate.

6. The substrate processing device according to claim 4, wherein the imaging unit is arranged at a fixed position, and images the nozzle, which arrived at the outer circumferential portion of the substrate from the position on the outer side of the substrate, and the outer circumferential portion of the substrate.

7. The substrate processing device according to claim 3, wherein
the discharging position detection unit includes,
an irradiation unit configured to irradiate the substrate with light, and
a detection unit configured to detect a light quantity of the light reflected by the substrate; and
the determination unit determines whether or not the discharging position arrived at the outer circumferential portion of the substrate based on the light quantity.

8. The substrate processing device according to claim 3, wherein
the discharging position detection unit moves with the nozzle; and
the determination unit corrects the discharging position based on a movement speed of the nozzle.

9. The substrate processing device according to claim 8, wherein the determination unit corrects the discharging position using an arrangement interval between the nozzle and the discharging position detection unit.

10. A nontransitory computer readable recording medium recorded with a control program for causing a computer to control a rotation number of a substrate, the nontransitory computer readable recording medium being recorded with a control program for causing the computer to carry out processes of:
determining whether or not a discharging position of chemical by a nozzle arrived at an outer circumferential portion of the substrate from a position on an outer side of the substrate; and
controlling the rotation number of the substrate based on a determination result of the determining process.

11. The nontransitory computer readable recording medium according to claim 10, wherein the control program causes the computer to rotate the substrate at a first rotation number for a predetermined time from when the discharging position arrives at the outer circumferential portion of the substrate, and rotate the substrate at a second rotation number greater than the first rotation number after the predetermined time has elapsed.

12. The nontransitory computer readable recording medium according to claim 10, wherein the control program causes the computer to determine whether or not the discharging position arrived at the outer circumferential portion of the substrate based on a position of the outer circumferential portion in an image in which the outer circumferential portion of the substrate is imaged.

13. The nontransitory computer readable recording medium according to claim 12, wherein
the image is imaged while moving with the nozzle; and
the control program causes the computer to determine whether or not the discharging position arrived at the outer circumferential portion of the substrate based on an image in which an upper surface of the substrate is imaged when the discharging position arrives at the outer circumferential portion of the substrate.

14. The nontransitory computer readable recording medium according to claim 12, wherein
the image is imaged while being arranged at a fixed position; and
the control program causes the computer to determine whether or not the discharging position arrived at the outer circumferential portion of the substrate based on an image in which the nozzle and the outer circumferential portion of the substrate are imaged when the nozzle arrives at the outer circumferential portion of the substrate from a position on the outer side of the substrate.

15. The nontransitory computer readable recording medium according to claim 10, wherein the control program causes the computer to determine whether or not the discharging position arrived at the outer circumferential portion of the substrate based on a light quantity of a light reflected by the substrate.

16. The nontransitory computer readable recording medium according to claim 10, wherein the determination unit corrects the discharging position based on a movement speed of the nozzle.

17. The nontransitory computer readable recording medium according to claim 16, wherein the control program causes the computer to correct the discharging position using an arrangement interval between the nozzle and a discharging position detection unit configured to detect the discharging position.

18. A control method comprising:
determining whether or not a discharging position of chemical by a nozzle arrived at an outer circumferential portion of a substrate from a position on an outer side of the substrate; and
controlling a rotation number of the substrate based on a result of the determination.

19. The control method according to claim 18, wherein in the controlling the rotation number, the substrate is rotated at a first rotation number for a predetermined time from when the discharging position arrives at the outer circumferential portion of the substrate, and the substrate is rotated at a second rotation number greater than the first rotation number after the predetermined time has elapsed.

20. The control method according to claim 18, wherein whether or not the discharging position arrived at the outer circumferential portion of the substrate is determined based on a position of the outer circumferential portion in an image in which the outer circumferential portion of the substrate is imaged.
